(19) United States
(12) Patent Application Publication
(10) Pub. No.: US 2013/0241057 A1
(43) Pub. Date: Sep. 19, 2013

(54) Methods and Apparatus for Direct Connections to Through Vias

(71) Applicants: Chen-Hua Yu, Hsin-Chu (TW); Yu-Hsiang Hu, Hsin-Chu (TW); Wen-Chih Chiou, Miaoli (TW); Sao-Ling Chiu, Hsin-Chu (TW); Shih-Peng Tai, Hsin-Chu (TW)

(72) Inventors: Chen-Hua Yu, Hsin-Chu (TW); Yu-Hsiang Hu, Hsin-Chu (TW); Wen-Chih Chiou, Miaoli (TW); Sao-Ling Chiu, Hsin-Chu (TW); Shih-Peng Tai, Hsin-Chu (TW)

(73) Assignee: Taiwan Semiconductor Manufacturing Company, Ltd., Hsin-Chu (TW)

(21) Appl. No.: 13/420,369

(22) Filed: Mar. 14, 2012

(51) Int. Cl. H01L 23/48; H01L 21/60

(52) U.S. Cl. 257/738; 257/737; 438/121; 257/E23.021; 257/E23.023; 257/E21.506

(57) ABSTRACT

Methods and apparatus for direct connection to a through via. An apparatus includes a substrate having a front side surface and a back side surface; conductive through vias formed in the substrate and having through via protrusions extending from the back side surface; solder connectors on another device and coupling the another device to the substrate, wherein the solder connectors correspond to the through via protrusions and enclose the through via protrusions to form solder joints; and connectors on the front side surface of the substrate for forming additional electrical connections. Methods include providing a substrate with through vias; thinning the substrate; etching the substrate to create through via protrusions; aligning another device with solder connectors on a surface corresponding to the through via protrusions; placing the solder connectors in contact with the protrusions; and performing a thermal reflow to form solder joints around the through via protrusions.

### BACKGROUND

Advances in packaging and integrated circuit assembly processes are increasing the use of integrated circuits or multiple integrated circuits mounted on interposers, wafers or substrates to form modules that are then subsequently mounted to printed circuit boards (PCBs) to form complete systems. For example, an integrated circuit may be mounted as a “flip chip” on a substrate that carries solder balls in a grid array to form a “flip chip ball grid array” or FC-BGA assembly; this assembly may then be mounted to a system board. Further advances include adding additional devices stacked over an integrated circuit to increase circuit density of the assembly, and remove some of the devices from using the limited area on the system board. As the use of increasingly advanced integrated circuits continues in ever smaller and denser devices, such as portable devices, increases, the need for smaller, thinner, and less costly techniques to couple integrated circuit devices and assembled modules to PCBs continues to increase.

Increasingly, the use of stacked arrangements such as stacked dies and package-on-package arrangements are used. Stacking devices reduces the area needed on the system board, and, increases the density of devices to provide system assemblies for mounting to a system board. For example, a memory IC or module may be assembled together with a logic IC, or processor chip. The stacked devices may then be mounted to a system board using solder connections, for example controlled collapse chip connectors (“C4”) or solder balls. In a typical arrangement, a solder bumped integrated circuit die may be mounted on the top surface of an interposer formed of a laminate material, silicon, ceramic, films and the like. The lower surface of the interposer may then have solder balls arranged in a pattern that corresponds to a ball land pad pattern on the PCB. After the integrated circuit or stacked die assembly is mounted on the interposer, the assembly may then be mounted on the system PCB.

In addition, through via connections may be made to further enable connectivity of the stacked devices to one another, or, to the system. Through vias provide vertical connections made through a device. When made through a silicon substrate, these may be referred to as “TSVs” or “through silicon vias”. In conventional arrangements, a redistribution layer or “RDL” may be formed in layers disposed over the ends of the through vias. Conductive pads may be formed on passivation layers over the substrate, and a solder bump or ball may be formed on the pads that are coupled to a trace portion of the RDL, to make an external connection to the through via. However these approaches add additional manufacturing steps to produce the RDL, add thickness to the assembly, and add costs and additional time for production.

### BRIEF DESCRIPTION OF THE DRAWINGS

For a more complete understanding of the illustrative embodiments, and the advantages thereof, reference is now made to the following descriptions taken in conjunction with the accompanying drawings, in which:

FIG. 1 depicts a cross-sectional view of an embodiment structure;

FIG. 2 depicts in a cross-sectional view an embodiment structure at an intermediate process step;

FIGS. 3A and 3B depict in cross-sectional views additional structures to illustrate processing steps of a method embodiment;

FIG. 4 depicts in a cross-sectional view the structure of FIG. 2 following additional processing;

FIG. 5 depicts in a cross-sectional view the structure of FIG. 4 following additional processing;

FIGS. 6A-6C depict intermediate structures in cross-sectional views to illustrate additional method embodiments;

FIG. 7 depicts in a cross-sectional view an intermediate structure to illustrate an additional method embodiment;

FIG. 8 depicts in a cross-sectional view another intermediate structure for an additional embodiment;

FIG. 9 depicts in an additional cross-sectional view an another intermediate structure embodiment;

FIG. 10 depicts in a cross-sectional view the embodiment of FIG. 9 following additional processing;

FIGS. 11A-11C depicts in cross-sectional views additional alternative embodiments;

FIGS. 12A and 12B depict in cross-sectional views additional embodiments;

FIG. 13 depicts in a flow diagram an example method embodiment; and

FIG. 14 depicts in a flow diagram another example method embodiment.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that an illustrative embodiment provides many applicable inventive concepts that can be embodied in a wide variety of specific contexts. The specific embodiments discussed are merely illustrative of specific ways to make and use the embodiments, and these examples do not limit the scope of this description and do not limit the scope of the appended claims.

The embodiments herein are illustrative examples but do not limit the scope of the disclosure and do not limit the scope of the appended claims. Embodiments of this disclosure include methods for forming a substrate connection to another board or device including through vias, using direct bumping connections. In embodiments, the through via conductors in a substrate, which may be an integrated circuit die or wafer, may be extended by removing additional substrate material to form an extended pillar or “nail” that protrudes from the surface of the substrate. These through via protrusions may then be placed in contact with a solder connection provided on another device or system board. A thermal reflow of the solder connection may be performed. The solder, during the reflow process, melts and encloses the through via protrusion material. In this manner the solder and the through via protrusion form a solder joint that provides both a physical bond and an electrical connection. Using the embodiment's direct connections may be made to the substrate through vias, without the need for intervening RDL layers, ball lands, or the added passivation or insulation layers and processes needed in the prior approaches. The substrate may be a wafer or a silicon integrated circuit with added functionality, such as a processor or logic device, or it might be a memory device. The substrate may be a semiconductor wafer and wafer level processing may be used. By removing the need for interposers, or RDL layers, such as used in the conventional devices, the assemblies formed by the embodiments are thinner and require less space within the finished devices. The embodiments also have fewer parts and this saves costs and simplifies manufacture.

Embodiments of this application enable face to face (“F2F”) bonding of devices. For example, a memory device or module may be disposed on the front or face side of a substrate that is, in an illustrative example, a logic integrated circuit having conductive through vias. The memory device is coupled using solder bumps to pads on the front side surface of the logic device. The entire assembly may then be mounted to a system board using the protruding through vias extending from the back side surface of the logic device. The substrate is coupled to the system board by the through via protrusions and a solder joint formed by a solder reflow. In this manner, the assembly is directly mounted to the system PCB without the need for an RDL layer on the substrate or an additional interposer. The assembly is not limited to the above example of a memory on logic (“MOL”) but may be extended to logic on logic (“LOL”) or to any device mounted on silicon, semiconductor wafers or other interposers having through vias.

In another embodiment, a front to back (“F2B”) arrangement is provided. An upper device, for example a memory integrated circuit device or module, is provided over the back side of a substrate, such as a wafer, logic integrated circuit device or an interposer. Through vias in the substrate include through via protrusions extending from the back side surface of the substrate. These through via protrusions are extended portions of the through via conductors. The protrusions are formed by exposing the through vias from the back side surface of the substrate, and the protrusions extend above the back side surface of the substrate. Solder connectors such as solder bumps on the upper device are placed in contact with the through via protrusions. A thermal reflow process is performed. The solder melts and forms solder connectors that enclose the protrusions, and the upper device is then physically bonded to the substrate; and the devices are also electrically connected by the solder and the through via protrusions. Solder balls or controlled collapse chip connection (“C4”) connectors formed on the remaining “face” or front side surface of the substrate can then be used, with a second conventional thermal reflow process, to mount the entire assembly to a system PCB board, for example.

Note that the term “through vias” is not limited to conductors that necessarily extend all the way through a substrate. The through vias, or at least some of them, may also be coupled to circuit devices formed within the substrate (for example, a logic integrated circuit) and may not necessarily provide an electrical path through the substrate without making any connections within the substrate. However, some through vias may provide an electrical connection entirely through a substrate and those are also used with the embodiments.

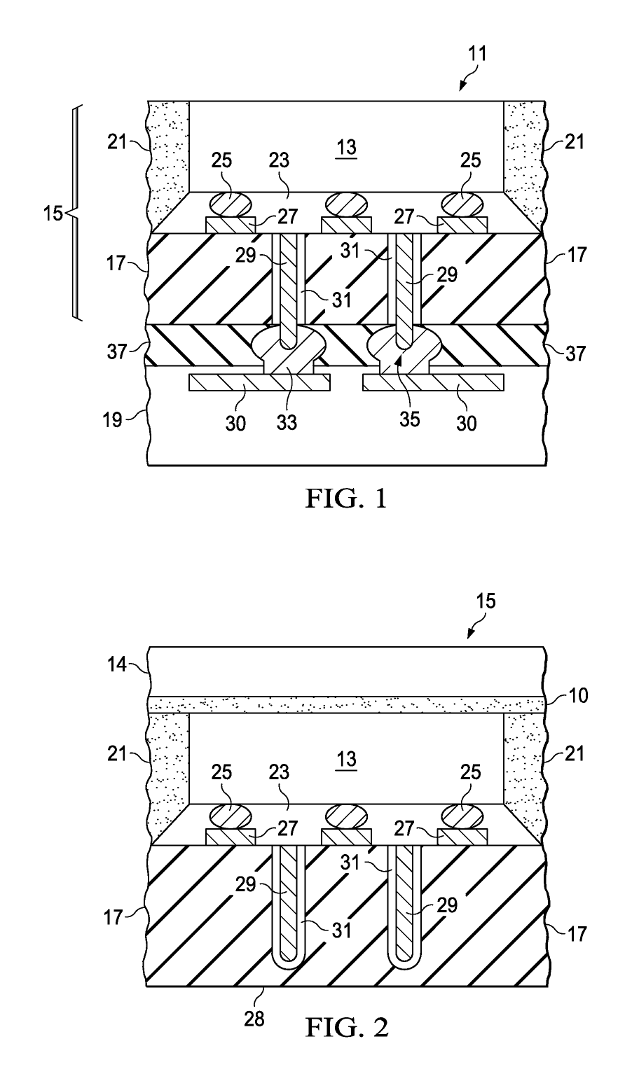

FIG. 1 depicts an embodiment structure 11 in a cross sectional view. An assembly 15 is mounted to a system board or substrate 19. Assembly 15 includes, in this non-limiting example, a memory die 13 mounted front side to front side (“F2F”) to a substrate 17, which may be a logic die or wafer, by solder on pad (“SOP”) connectors 25 on pads 27. These solder connectors 25 may be, for example, solder bumps, or columns, or pillars. Copper connectors could be used as well. An underflow 23 is shown beneath the memory die and protecting the solder connections between the logic die 17 and the memory die 13. A mold compound 21, such as an epoxy resin, epoxy, or resin, which may be formed by transfer molding or other mold compound formation, is shown surrounding memory die 13.

Through vias 29 are formed in the logic die 17 and may be surrounded by a barrier layer 31. The through vias, if the substrate 17 is silicon, may sometimes be referred to as “through silicon vias” or (“TSVs”), but the embodiments and claims herein are not to be limited to silicon devices or silicon wafers, so the term through vias is used in this application. Through vias 29 are formed of conductive material and may be formed, for example, of copper or other conductive materials. Plating or use of conductive plugs can form the conductive materials. Barrier layer 31 may be a diffusion barrier to prevent the conductive through via material from outdiffusion into the substrate material.

The through vias 29 each have a protruding portion 35 that extends from substrate 17 on the back side. In the embodiment of structure 11, protrusions 35 extend into solder connectors 33, which may be, for example, solder bumps or solder balls. The solder connectors 33 surround and enclose the through via protrusions 35, and the through via protrusions make electrical connection to the solder connectors 33, which are coupled to pads 30. Pads 30 may be part of a redistribution layer including conductive traces in the system board 19.

By making connections from the substrate 17 directly to the system board 19, without use of interposers or additional redistribution layers (“RDL”) on the substrate 17, the direct through via connections 29 to the solder balls form an assembly 11 that is thinner, and has fewer parts and is simpler to manufacture, than conventional mounting arrangements used in prior approaches.

FIG. 2 depicts assembly 15 from FIG. 1 in a cross sectional view at an intermediate process step. This intermediate step is presented to illustrate an example method embodiment for forming the structure shown in FIG. 1. In FIG. 2, the substrate 17, which may be, as non-limiting examples, a logic die, another integrated circuit die, a semiconductor wafer or other substrate, is shown with the memory die 13 disposed in a F2F fashion, that is the memory die is coupled to the logic die by solder bumps over pads, and the solder connection is made between the front surfaces of both devices. The use of the word “solder” in this application includes without limitation both lead-based and lead-free solders, such as lead tin (Pb—Sn) compositions for lead-based solder, and lead free solders including tin, copper, and silver, (“SAC”) compositions, and other eutectics that have a common melting point and which form conductive solder connections for use in electrical applications. For lead free solder, SAC solders of varying compositions may be used, such as SAC 105 (Sn 98.5%, Ag 1.0%, Cu 0.5%), SAC 305, SAC 405 and the like. Lead free solder connectors such as solder balls may be formed from Sn—Cu compounds as well, with or without the use of silver (Ag).

The substrate 17 may be a semiconductor substrate such as silicon, germanium, gallium arsenide, and other semiconductor materials. The substrate may be an interposer, such as a silicon, laminate, ceramic, film, BT resin, FR4, or other circuit board material and the embodiments may be applied to those substrates as well. The substrate, in some embodiments, is a silicon wafer comprising many integrated circuits fabricated in a semiconductor process prior to performing the method embodiments described here to form the connections to the system board.

Wafer level processing (“WLP”) is contemplated as an example method embodiment, but this application and the appended claims are not limited to WLP. The substrate 17 may also be a single integrated circuit die if wafer level processing is not used.

The cross sectional view of FIG. 2 depicts the through vias 31 formed in the substrate 17. The assembly 15 is mounted, temporarily, to a carrier 14 by glue or tape or other removable adhesive 10. Carrier 14 may be a wafer, or another carrier such as stainless steel, ceramic and the like.

At this stage, the through vias 31 are conductor filled vias, but are not yet exposed at the back side of the substrate 17, which is indicated as element 28 at the bottom of the substrate in FIG. 2. The through vias 29 may be formed, for example, by deep reactive ion etch (dRIE) plasma etching of the substrate 17; then a barrier layer 31 may be formed, such as a diffusion barrier layer. A copper electroplating process may be used to fill the vias to form the through vias 29. Alternatives for through via formation may be used, such as laser drilling.

FIG. 2 depicts the assembly 15 following a wafer thinning or back grinding operation on surface 28. The back grinding may be performed using carrier 14 as a support. A portion of the substrate 17 back side surface 28 is removed, while a portion remains covering the bottom of the through vias 29. The end of the through vias may be covered by at least about 5 microns, or more. This remaining part of the substrate 17 extends past the bottom of the through vias 29, to protect the through vias during the back grinding or thinning operations. Wafer thinning may be performed using material removal processes such as mechanical grinding, chemical-mechanical polishing (“CMP”), etching, or combinations of these.

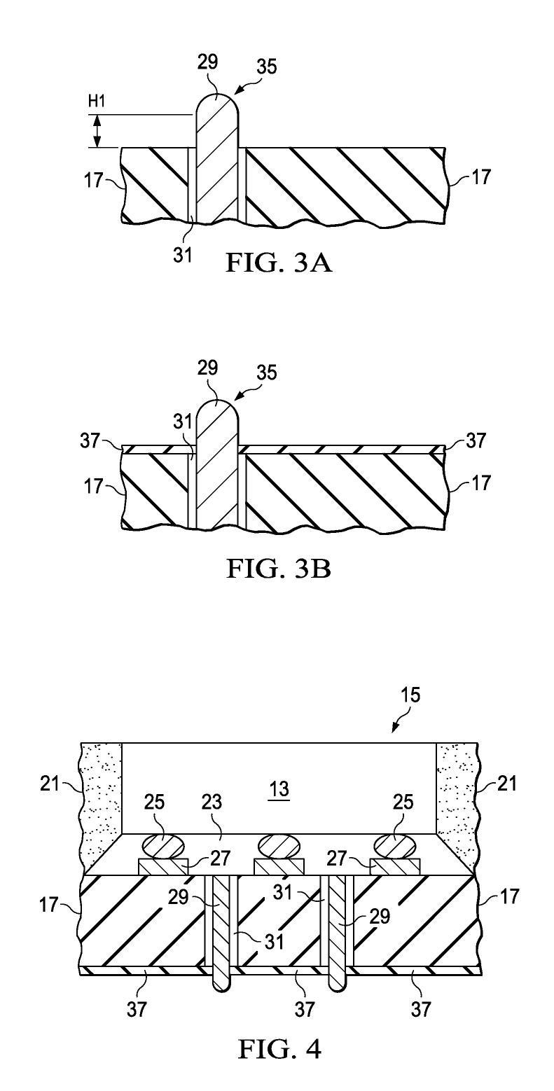

FIGS. 3A and 3B depict in cross sectional views the structures obtained by performing example method embodiments for exposing the through via protrusions. In FIG. 3A, a through via 29 is shown with protrusion 35 extending above the surface of substrate 17. This structure may be obtained by etching the back side surface of substrate 17 following the wafer thinning shown in FIG. 2. A combination of dry and wet etching may be used, such as a plasma recessing etch followed by a chemical wet etch, to expose through via 29, which has a rounded protrusion 35. However the rounded shape is but one example shape that is obtained using certain etch processes, other end shapes such as a flat end, square end or a spike shape, are also possible. The height “H1” of the protrusion 35 should be at least 3 microns, and may be, in one example process, from 3-10 microns. Other heights are also possible and these other heights form alternative embodiments for the through via protrusions 35.

FIG. 3B then illustrates the through via protrusion of FIG. 3A in another cross sectional view, following additional method steps. In FIG. 3B, a passivation layer 37 is shown over the substrate 17. This passivation material may be any known material for semiconductor passivation or stress relief, such as silicon or other nitrides, oxides, polymers, polyimide, benzo-cyclobutene (BCB), polybenzoxazole (PBO), films and tapes. If the protrusions 35 have sufficient height above the surface of the substrate 17, the protrusions 35 may not require further photolithographic processing to remove any coating material. In an example, the protrusions had a height of about 10 microns and this was sufficient. As described further below, in other embodiment methods that are contemplated as alternatives, additional photolithographic processing may be performed after the passivation and stress relief coatings are formed.

FIG. 4 depicts the assembly 15 in cross section after the through via protrusions 35 are completed. The assembly 15 is now ready for mounting to a system substrate. The protrusions 35 are shown extending downwardly in this particular orientation. The through via protrusions 35 extend from substrate 17 and the passivation layer 37 is shown over the substrate. Solder connections 25 and pads 27 are shown between the memory die 13 and the substrate 17 and surrounded by underfill 23. The devices 13 and 17 are shown in a F2F arrangement.

After the assembly 15 is complete with the through via protrusions 35 exposed and ready for solder reflow, a debonding and wafer dicing process may be used to separate individual devices from a wafer (when WLP is used). Wafer dicing may be performed using wafer sawing, for example.

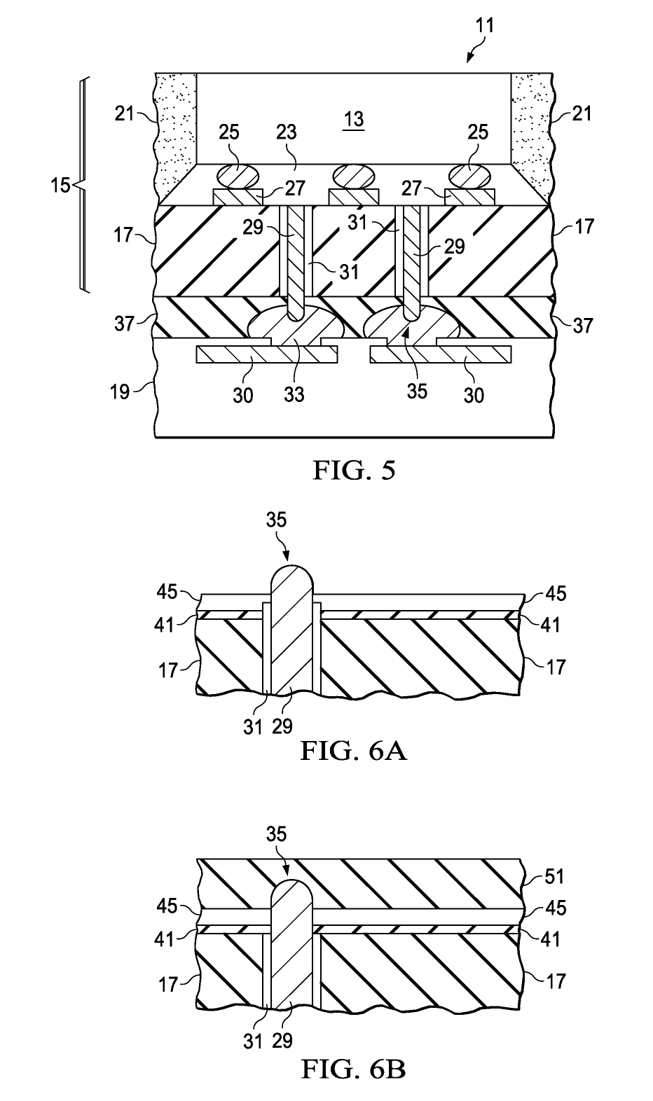

FIG. 5 depicts the assembly 15 mounted on a system board 19 just prior to a thermal reflow step. Solder pre-forms 33 are provided on pads or lands of the system board 19. The through via protrusions 35 of the substrate 17 are disposed on or in these solder pre-forms 35. A no-flow underfill (“NUF”) 37 is shown surrounding the solder 35, this may be omitted, or other underfill materials may be used, such as capillary underfill, or no underfill at all, for example. The remaining elements of FIG. 5 are the assembly 15 as shown in FIG. 4, with like reference numerals, and are not further described here. Pick and place equipment, including automated or manually operated equipment, may place the assembly 15 on the system board. The structure 11 is now ready for a thermal reflow step to mount the assembly 15 on the system board 19.

Referring again to FIG. 1, the method embodiment now continues by performing the thermal reflow on the structure of FIG. 5, to form the solder connectors 33 as shown in FIG. 1. The solder 33 melts and reforms to surround the through via protrusions 35 and to complete the embodiment of a F2F arrangement mounted to a system board.

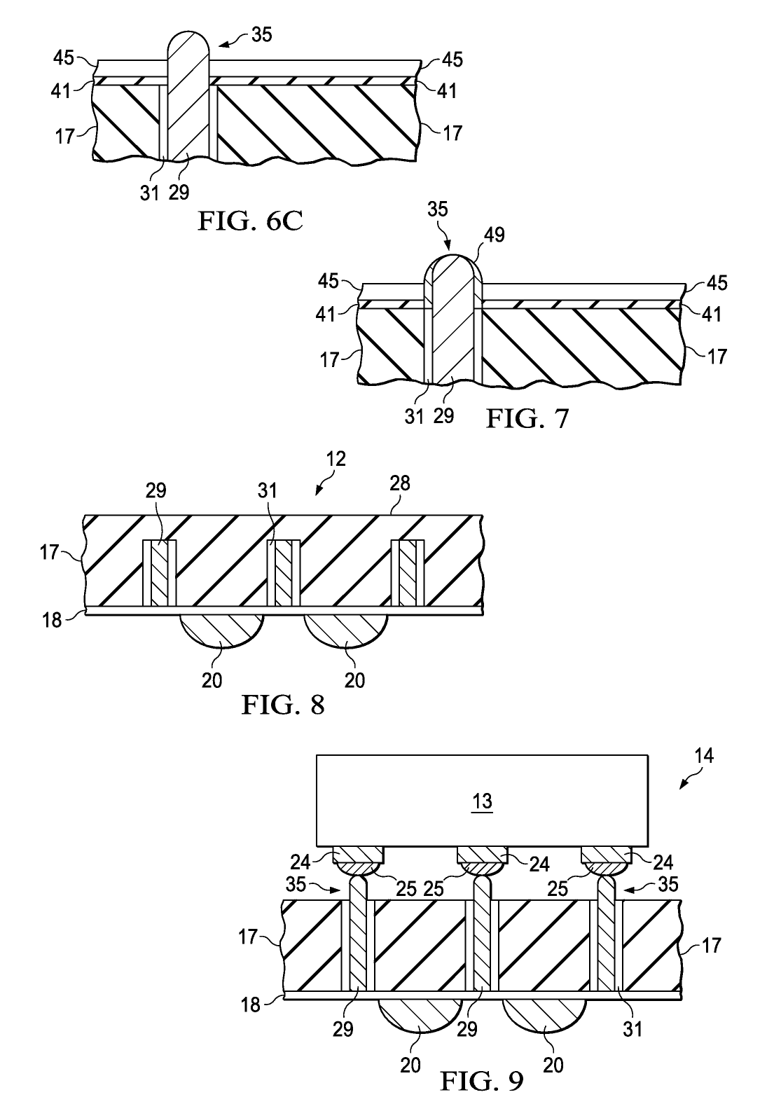

FIGS. 6A, 6B and 6C illustrate alternative methods for exposing and processing the through via protrusions, as alternatives to the steps illustrated in FIGS. 3A and 3B above. In FIG. 6A, the through via 29 is shown in a cross section being processed after the intermediate step of FIG. 2 and a passivation layer such as for example, silicon nitride 41 is formed, followed by a stress buffer 45, which may be a polyimide, PBO, BCB, non-photo sensitive polymer or the like.

In FIG. 6B, a cross sectional view depicts the through via of FIG. 6A following a PR deposition step. Photoresist (PR) 51 is deposited and coats the substrate 17 including the through via 29 and the layers 41 and 45. This enables a photolithographic process to perform an etch back or additional patterning. The PR enables the coatings 41, 45 to be removed from the through via protrusions 35, for example, if needed. For example, if the protrusions 35 are not high enough above the substrate 17 surface to avoid the passivation or stress buffer coating materials from forming on the protrusions 35, additional photolithography may be needed to prevent the coating of the protrusions 35, or remove it.

In FIG. 6C, a cross sectional view depicts the finished through via with protrusion 35 exposed shown after a PR strip removes the photoresist 51. The substrate and through vias are then ready for assembly as shown in FIGS. 4, 5 and described above.

FIG. 7 depicts, in another cross sectional view, yet another alternative embodiment. In the embodiment of FIG. 7, through via 29 with protrusion 35 is shown following the formation of a passivation layer 41 and a protective coating 45, as described above. The protrusions 35 may then be coated with a surface finish 49. This surface finish 49 prevents, for example, the copper of a through via protrusion 35 from being totally consumed by an intermetallic compound (“IMC”) formed with the solder during the subsequent reflow processes. Surface finishes used for conductors in integrated circuit assemblies such as nickel (Ni), gold (Au), palladium (Pd) and combinations of these may be used. In an example embodiment, nickel-gold (Ni—Au) plating is used. In another embodiment, an electro-less copper (Cu) is used to add additional material to the protrusion 35. In another example embodiment, the surface finish 49 may be an electroless plating such as electroless nickel, electroless palladium, immersion gold (ENEPIG), or electroless nickel immersion gold (ENIG). The through via protrusions 35 with the surface finish 49 are now ready for further assembly as shown in FIGS. 4, and 5, above.

FIG. 8 depicts, in a cross sectional view, a first intermediate structure 12 for use in illustrating methods for forming an embodiment using a front to back or F2B arrangement. In FIG. 8, substrate 17 is depicted with through vias 29 extending upwards from the front side surface as oriented in the figure. The front side of the substrate 17 is shown with a passivation or protective layer 18 and solder connectors 20 overlying it. The connectors 20 may be solder balls or C4 connections, for example. The solder connectors 20 may be used to mount the substrate 17 onto a system board, using a thermal reflow step. Note that the back side surface 28 of the substrate 17 is now shown at the upper portion of the figure, that is the substrate 17 is now oriented with its front side down, that is, opposite of the orientation shown in FIG. 2.

The substrate 17 is processed in a wafer thinning or backgrinding operation. The substrate 17 may be mounted to a carrier on its front side with an adhesive to support the substrate 17 during the wafer thinning operation. Mechanical grinding, CMP, and or etch processing may be used to thin substrate 17 so that about 5 microns or more remains above the ends of the through vias 29.

FIG. 9 depicts in another cross sectional view a structure 14. Structure 14 includes a memory die 13 with a front surface positioned over the back side of substrate 17 and having solder connectors 25 that are aligned with the through via protrusions 35. Several steps were performed to transition from the structure 12 in FIG. 8 to intermediate structure 14 shown in FIG. 9. The substrate 17 was subjected to the wet and dry etch processes to expose the through via protrusions 35, as described above with respect to FIGS. 3A, 3B and 3C for example. A memory die 13 is then carried over and disposed on the substrate 17 as shown. The solder connectors 25 are formed prior to assembly on pads 24, which couple to circuitry in the device 13, which in one example is a memory die, although other devices may be mounted to the substrate 17 using the embodiments. The protrusions 35 may be processed using the PR methods described above with respect to FIGS. 6A, 6B and 6C. Alternatively the protrusions 35 may include the surface finish embodiments described above with respect to FIG. 7, for example.

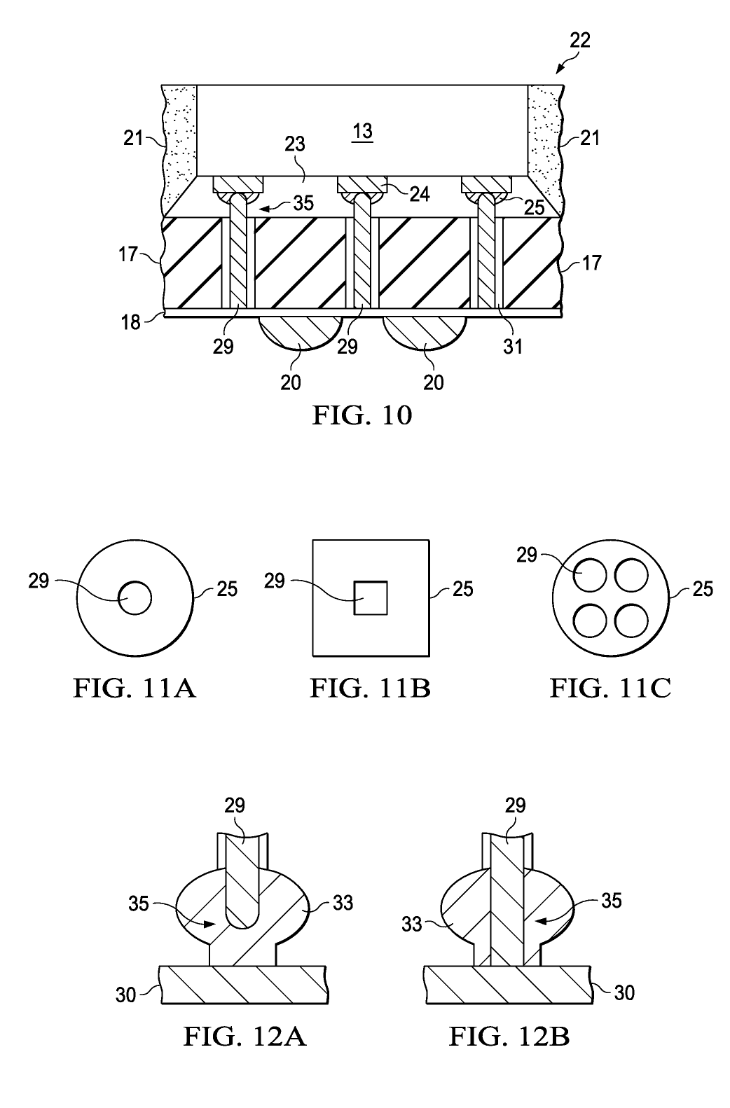

FIG. 10 depicts an embodiment 22 which illustrates the structure obtained from the structure 14 in FIG. 9 following additional process steps. In transitioning to FIG. 10, the solder connectors 25 are subjected to a reflow step. The solder connectors 25 then melt and enclose the through via protrusions 35 and make electrical connections and physical bonds to the through vias 29. An underfill 24 is dispensed beneath the die 13 and surrounding the solder connections. This may be, for example, a capillary underfill, NUF, or other underfill material. An overmolding process forms mold compound 21 around the upper portion of the assembly to provide additional protection and moisture resistance. If WLP processing is used, the assembly 22 may now be singulated to separate the wafer 17 into individual units. This may be done by wafer sawing operations, or laser cutting, for example.

The assembly 22 may then be mounted to a system board using conventional thermal reflow and underfill processes. This embodiment F2B assembly provides a memory and integrated circuit in a solder ball or BGA assembly, without the need for added redistribution layers over the substrate 17, providing a thinner overall assembly at lower cost and with fewer parts.

FIGS. 11A, 11B and 11C depict in horizontal cross sections alternative arrangements for the through vias and solder connectors described above. The through vias 29 may be cylindrical, as shown in FIG. 11A, and may be surrounded by a solder ball 25. However, as shown in FIG. 11B, the through vias 29 may be square or rectangular columns, and may be surrounded by solder columns 25; these are additional alternative embodiments. In FIG. 11C another alternative embodiment is shown in cross section, where a plurality of through vias 29 is shown in a single solder connection 25. The use of multiple through via protrusions can add additional strength and robustness to the solder joints between the substrate and the solder connectors.

FIGS. 12A and 12B depicts in vertical cross sections two alternative connections that may be formed between the through via protrusions 35 and the solder connectors and underlying pads. In FIG. 12A, a “suspend” arrangement is shown where the through via protrusion 35 ends in the central portion of the solder connector 33 and does not contact the pad 30, but is suspended away from it. FIG. 12B depicts, in a vertical cross section another alternative, a “contact” arrangement, where the through via protrusions 35 extend through the solder connector 33 to the underlying pad 30 and make physical contact to the pad 30. This contact arrangement provides an additional conductive path between the devices (in addition to the conductive solder). Further, in case of a solder ball crack due to a thermal stress, for example, this added electrical path may help prevent an “open” from developing.

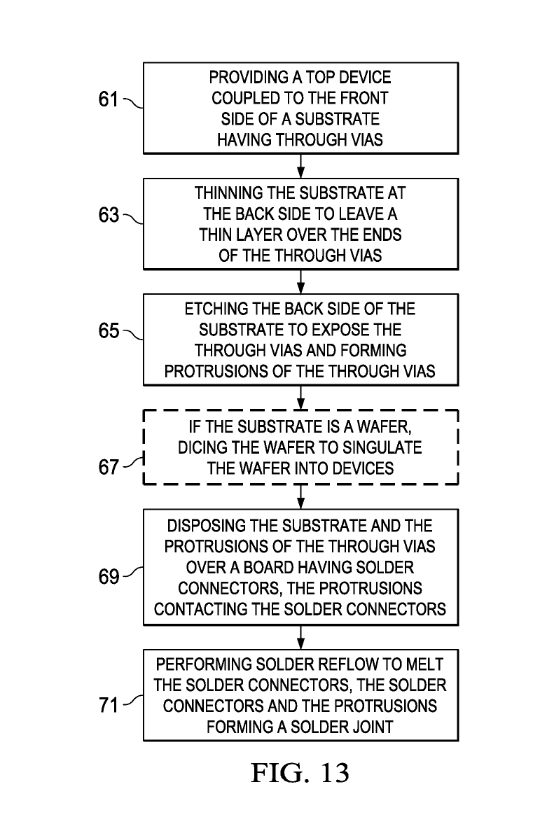

FIG. 13 depicts, in a flow diagram, the steps of an example method embodiment for forming the F2F assembly, described above. In step 61a device is coupled to the front side of a substrate that includes through vias. For example, the structure of FIG. 2 above shows a memory device mounted in F2F arrangement on a logic device. In step 63, the back side surface of the substrate is thinned, for example in a wafer thinning operation as described above. In step 65, the back side of the substrate is etched, using wet or dry etches or both, to form the through via protrusions extending from the back side surface. At step 67, which is dashed to show this is an optional step, if the substrate is a wafer for a WLP process, the wafer may be debonded and diced into single units (singulated). In step 69, the substrate with the extending protrusions is disposed over a board having solder connectors formed on it, and the protrusions are placed in contact with the solder connectors. In step 71, a solder reflow step melts the solder connectors, which then surround the protrusions and form a solder joint, coupling the through vias to the system board.

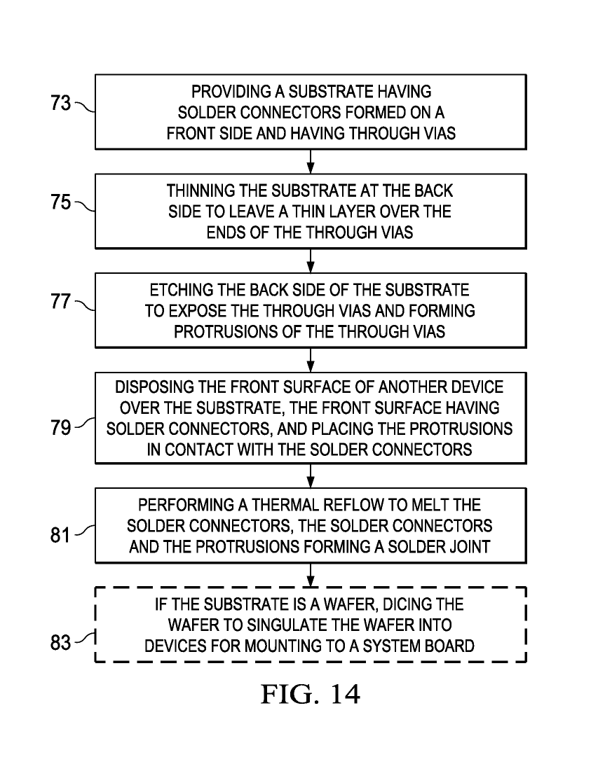

FIG. 14 depicts in a flow diagram an alternative method embodiment for forming a F2B assembly. In step 73, a substrate is provided having solder connectors, for example solder balls, on a front side for connecting to a system board, and having through vias. In step 75 the substrate is thinned at the back side surface to leave a thin layer over the ends of the through vias. In step 77 etching is performed to expose the through vias at the back side and form the through via protrusions extending from the back side of the substrate.

In step 79, a device is disposed over the back side surface having solder connectors on its front side surface, and the solder connectors are placed in contact with the through via protrusions.

In step 81a thermal reflow is performed, and the solder connectors melt and enclose the through via protrusions, forming solder joints between the substrate and the device.

Step 83 is shown as an optional wafer dicing step, if wafer level processing is used, the substrate is separated by wafer dicing into single units. The substrate assembly units are then ready to be mounted to a system board using the solder connectors on the front side of the substrate in a conventional solder ball mount process.

Use of the embodiments provide improved methods and structures forming direct connections to through vias in mounting integrated circuit assemblies on system boards, without requiring the use of redistribution layers or intermediate interposers. The use of the through via protrusions to form a connection to solder on another device or board eliminates layers used in prior through via assemblies. Solder connectors including the embodiments may be reliably used to directly mount the through vias of integrated circuits, substrates or interposers to solder connectors on system boards, for example. Wafer level processing is also contemplated. The assemblies may further incorporate a memory die or other device mounted on top of the substrate or wafer, to increase circuit density and provide additional system functionality without adding to the device area needed on the system board. Embodiments can provide F2F or F2B connections between devices.

In an embodiment, an apparatus includes a substrate having a front side surface and a back side surface; conductive through vias formed in the substrate and having through via protrusions extending from the back side surface; solder connectors on another device and coupling the another device to the substrate, wherein the solder connectors correspond to the through via protrusions and enclose the through via protrusions to form solder joints; and connectors on the front side surface of the substrate for forming additional electrical connections.

In a further embodiment, in the above apparatus the substrate is a semiconductor wafer. In another apparatus embodiment, the substrate is a logic device. In still a further embodiment, in the above apparatus the another device is a memory device mounted front to back over the back side of the substrate. In yet another embodiment, in the above apparatus, the another device is a system board, and the substrate is mounted with its back side facing the system board. In still another apparatus embodiment, a third device is mounted on the front side of the substrate. In still a further apparatus embodiment the third device is one or more memory devices. In a further apparatus embodiment, the solder connectors are solder balls. In still another embodiment, in the above apparatus the through via protrusions further comprise a finish plating that is one selected from the group consisting essentially of gold, nickel, copper, palladium, electroless nickel-immersion gold (ENIG), and electroless nickel, electroless palladium, immersion gold (ENEPIG).

In another embodiment, in the above apparatus, the through via protrusions extend from the back side of the substrate between 3 and 10 microns. In still a further embodiment, in the above apparatus, the through via protrusions comprise copper.

Another apparatus embodiment includes a semiconductor wafer having a plurality of devices formed therein, and having a front side surface and a back side surface; through vias formed in the semiconductor wafer and having through via protrusions extending from the back side surface of the semiconductor wafer; solder connections formed on another device and enclosing the through via protrusions to form a solder joint adjacent the back side surface of the semiconductor wafer; and solder connections formed on the front side surface of the semiconductor wafer.

In a further embodiment, in the above apparatus, the solder connections on the another device overlie a pad, and the through via protrusions extend through the solder connections to contact the pad. In yet another apparatus, the solder connections are solder bumps. In still a further apparatus, the another device is an integrated circuit.

In a method embodiment, the method includes providing a substrate having a front side surface and a back side surface, and having a plurality of conductive through vias disposed in the substrate; thinning the back side of the substrate to provide a thin layer over ends of the conductive through vias in the substrate; etching the back side surface of the substrate to expose the through vias and removing material from the back side of the substrate to create conductive through via protrusions extending from the back side surface of the substrate; providing another device having solder connectors on a surface; positioning the substrate and the another device so that the solder connectors contact the conductive through via protrusions; and performing a thermal reflow to melt the solder of the solder connectors to surround the conductive through via protrusions and form a solder joint.

In a further embodiment, providing a substrate comprises providing a semiconductor wafer. In still another embodiment, providing another device having solder connectors on a surface comprises providing a memory device having solder bumps on a surface. In still a further embodiment, the method above is performed and after creating the through via protrusions extending from the back side of the substrate, forming a finish plating on the conductive through via protrusions that is one selected from the group consisting essentially of gold, nickel, copper, palladium, electroless nickel-immersion gold (ENIG), and electroless nickel, electroless palladium, immersion gold (ENEPIG). In another embodiment, the above method further includes mounting the substrate to a system board using solder connectors formed on the front side surface of the substrate in a thermal reflow process.

Although the illustrative embodiments and advantages have been described in detail, it should be understood that various changes, substitutions, and alterations can be made herein without departing from the spirit and scope of the appended claims. For example, alternate materials, implant doses and temperatures may be implemented.

Moreover, the scope of the present application is not intended to be limited to the particular embodiments of the process, machine, manufacture, composition of matter, means, methods, and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. An apparatus, comprising:
a substrate having a front side surface and a back side surface;
conductive through vias formed in the substrate and having through via protrusions extending from the back side surface, the through via protrusions having protruding portions of a diameter not greater than the greatest diameter of the conductive through vias in the substrate;
solder connectors on another device and coupling the another device to the substrate, wherein the solder connectors correspond to the through via protrusions and the solder connectors comprise a solder configured to enclose the protruding portions of the through via protrusions to form solder joints; and
connectors formed directly on the front side surface of the substrate for forming additional electrical connections.

2. The apparatus of claim 1, wherein the substrate is a semiconductor wafer.

3. The apparatus of claim 1, wherein the substrate is a logic device.

4. The apparatus of claim 1, wherein the another device is a memory device mounted front to back over the back side of the substrate.

5. The apparatus of claim 1, wherein the another device is a system board, and the substrate is mounted with its back side facing the system board.

6. The apparatus of claim 5, and further comprising a third device mounted on the front side of the substrate.

7. The apparatus of claim 6, wherein the third device is one or more memory devices.

8. The apparatus of claim 1, wherein the solder connectors are solder balls formed directly on the front side surface of the substrate.

9. The apparatus of claim 1, wherein the through via protrusions further comprise a finish plating on at least the protruding portions of the through via protrusions that is one selected from the group consisting essentially of gold, nickel, copper, palladium, electroless nickel-immersion gold (ENIG), and electroless nickel, electroless palladium, immersion gold (ENEPIG).

10. The apparatus of claim 1, wherein the through via protrusions extend from the back side of the substrate between 3 and 10 microns.

11. The apparatus of claim 1, wherein the through via protrusions comprise copper.

12. An apparatus, comprising:
a semiconductor wafer having a plurality of devices formed therein, and having a front side surface and a back side surface;
through vias formed in the semiconductor wafer and having through via protrusions extending from the back side surface of the semiconductor wafer, the through via protrusions having a diameter not greater than the greatest diameter of the through vias in the substrate and ending in a protruding portion;
solder connections formed on another device and enclosing the protruding portions of the through via protrusions to form a solder joint adjacent the back side surface of the semiconductor wafer; and
solder connections formed directly on pads on the front side surface of the semiconductor wafer.

13. The apparatus of claim 12, wherein the solder connections on the another device overlie a pad, and the through via protrusions extend through the solder connections to enable the protruding portion of the through via protrusions to contact the pad.

14. The apparatus of claim 13 wherein the solder connections are solder bumps.

15. The apparatus of claim 12, wherein the another device is an integrated circuit.

16. A method, comprising:
providing a substrate having a front side surface and a back side surface, and having a plurality of conductive through vias disposed in the substrate, the substrate having solder connectors formed directly on pads on the front side surface, wherein at least one of the solder connectors is coupled to at least one of the plurality of conductive through vias;
thinning the back side of the substrate to provide a thin layer of the substrate over ends of the conductive through vias in the substrate;
following the thinning, chemically etching the back side surface of the substrate to expose the through vias and removing material from the back side of the substrate to create conductive through via protrusions extending from the back side surface of the substrate, the conductive through via protrusions having protruding portions with a diameter smaller than the diameter of the conductive through vias in the substrate;
providing at least one integrated circuit device having solder connectors on a surface;
positioning the substrate and the at least one integrated circuit device so that the solder connectors on the at least one integrated circuit contact the conductive protruding portions of the through via protrusions; and
performing a thermal reflow to melt the solder of the solder connectors on the at least one integrated circuit to surround at least the protruding portions of the conductive through via protrusions and form a solder joint.

17. The method of claim 16, wherein providing the substrate comprises providing a semiconductor wafer.

18. The method of claim 16, wherein providing the at least one integrated circuit device having solder connectors on the surface comprises providing a memory device having solder bumps on a surface.

19. The method of claim 16, and further comprising:
after chemically etching the substrate to form through via protrusions extending from the back side of the substrate, forming a finish plating on at least the protruding portions of the conductive through via protrusions that is one selected from the group consisting essentially of gold, nickel, copper, palladium, electroless nickel-immersion gold (ENIG), and electroless nickel, electroless palladium, immersion gold (ENEPIG).

20. The method of claim 16, and further comprising:
mounting the substrate to a system board using solder connectors formed directly on pads on the front side surface of the substrate in a thermal reflow process.
